(19) United States
(12) Patent Application Publication
(10) Pub. No.: US 2025/0349779 A1
(43) Pub. Date: Nov. 13, 2025

(54) DIE STRUCTURES AND METHODS OF FORMING THE SAME

(71) Applicant: Taiwan Semiconductor Manufacturing Co., Ltd.,, Hsinchu (TW)

(72) Inventors: Chia-Hao Hsu, Hsinchu (TW); Jian-Wei Hong, Taoyuan City (TW); Kuo-Chiang Ting, Hsinchu (TW); Sung-Feng Yeh, Taipei City (TW)

(21) Appl. No.: 19/274,022

(22) Filed: Jul. 18, 2025

Related U.S. Application Data
(63) Continuation of application No. 18/151,856, filed on Jan. 9, 2023.
(60) Provisional application No. 63/374,793, filed on Sep. 7, 2022.
(60) Provisional application No. 63/427,296, filed on Nov. 22, 2022.

(51) Int. Cl. H01L 23/00; H01L 21/56; H01L 23/29; H01L 23/31; H01L 25/00; H01L 25/065; H01L 25/18; H10B 80/00

(52) U.S. Cl. CPC H01L 24/20; H01L 21/56; H01L 23/291; H01L 23/293; H01L 23/3128; H01L 23/3135; H01L 24/05; H01L 24/08; H01L 24/19; H01L 24/24; H01L 24/80; H01L 24/92; H01L 24/94; H01L 24/97; H01L 25/0652; H01L 25/0657; H01L 25/18; H01L 25/50; H10B 80/00; H01L 2224/05571; H01L 2224/05624; H01L 2224/05639; H01L 2224/05644; H01L 2224/05647; H01L 2224/05684; H01L 2224/19; H01L 2224/214; H01L 2224/215; H01L 2224/24105; H01L 2224/24146; H01L 2224/244; H01L 2224/80201; H01L 2224/80357; H01L 2224/80379; H01L 2224/80895; H01L 2224/80896; H01L 2224/9212; H01L 2224/9222; H01L 2224/94; H01L 2224/97; H01L 2225/06524; H01L 2225/06541; H01L 2924/01013; H01L 2924/01029; H01L 2924/01047; H01L 2924/01074; H01L 2924/01079; H01L 2924/0504; H01L 2924/0544; H01L 2924/0549; H01L 2924/05494; H01L 2924/07025

(57) ABSTRACT

Die structures and methods of forming the same are described. In an embodiment, a device includes: a lower integrated circuit die; a first upper integrated circuit die face-to-face bonded to the lower integrated circuit die, the first upper integrated circuit die including a first semiconductor substrate and a first through-substrate via; a gap-fill dielectric around the first upper integrated circuit die, a top surface of the gap-fill dielectric being substantially coplanar with a top surface of the first semiconductor substrate and with a top surface of the first through-substrate via; and an interconnect structure including a first dielectric layer and first conductive vias, the first dielectric layer disposed on the top surface of the gap-fill dielectric and the top surface of the first semiconductor substrate, the first conductive vias extending through the first dielectric layer to contact the top surface of the first through-substrate via.

### PRIORITY CLAIM AND CROSS-REFERENCE

This application is a continuation of U.S. patent application Ser. No. 18/151,856, filed Jan. 9, 2023, entitled “Die Structures and Methods of Forming the Same,” which claims the benefit of U.S. Provisional Application No. 63/427,296, filed on Nov. 22, 2022 and U.S. Provisional Application No. 63/374,793, filed on Sep. 7, 2022, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2-11 are cross-sectional views of intermediate stages in the manufacturing of a die structure, in accordance with some embodiments.

FIG. 12-14 are cross-sectional views of die structures, in accordance with some embodiments.

FIGS. 15-17 are cross-sectional views of intermediate stages in the manufacturing of a die structure, in accordance with some embodiments.

FIG. 18-20 are cross-sectional views of die structures, in accordance with some embodiments.

FIGS. 21-26 are cross-sectional views of intermediate stages in the manufacturing of a die structure, in accordance with some embodiments.

FIG. 27-30 are cross-sectional views of die structures, in accordance with some embodiments.

FIG. 31-35 are cross-sectional views of die structures, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a die structure is formed by bonding integrated circuit dies in a face-to-face manner. An upper integrated circuit die of the die structure includes a semiconductor substrate and through-substrate vias (TSVs), and a back-side interconnect structure for the die structure is electrically coupled to the integrated circuit dies through the TSVs. The back-side interconnect structure includes an additional layer of conductive vias that are in contact with the TSVs. Utilizing the additional layer of conductive vias may obviate a process for recessing the semiconductor substrate of the upper integrated circuit die. Omitting the recessing of the semiconductor substrate may help reduce pin hole defects in the die structure.

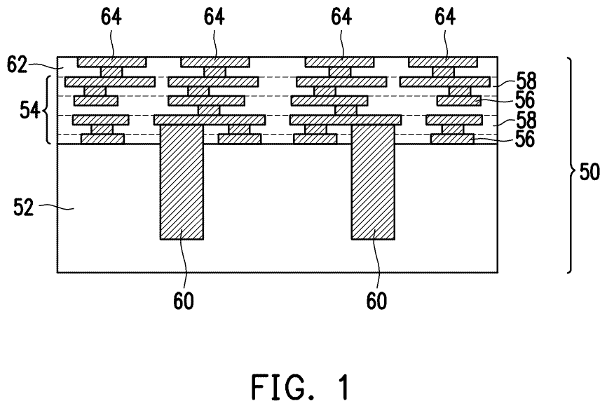

FIG. 1 is a cross-sectional view of an integrated circuit die 50. The integrated circuit die 50 will be bonded to other dies in subsequent processing to form a die structure. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front-side, and an inactive surface (e.g., the surface facing downwards in FIG. 1), sometimes called a back-side.

Devices (not separately illustrated) are disposed at the active surface of the semiconductor substrate 52. The devices may be active devices (e.g., transistors, diodes, etc.), capacitors, resistors, etc. An interconnect structure 54 is disposed over the active surface of the semiconductor substrate 52. The interconnect structure 54 interconnects the devices of the semiconductor substrate 52 to form an integrated circuit. The interconnect structure 54 may be formed of, for example, metallization patterns 56 in dielectric layers 58. The dielectric layers 58 may be, e.g., low-k dielectric layers 58. The metallization patterns 56 include metal lines and vias, which may be formed in the dielectric layers 58 by a damascene process, such as a single damascene process, a dual damascene process, or the like. The metallization patterns 56 may be formed of a suitable conductive material, such as copper, tungsten, aluminum, silver, gold, a combination thereof, or the like, which can be formed by, for example, plating or the like. The metallization patterns 56 are electrically coupled to the devices of the semiconductor substrate 52.

Optionally, conductive vias 6o extend into the interconnect structure 54 and/or the semiconductor substrate 52. The conductive vias 6o are electrically coupled to the metallization patterns 56 of the interconnect structure 54. As an example to form the conductive vias 6o, recesses can be formed in the interconnect structure 54 and/or the semiconductor substrate 52 by, for example, etching, milling, laser techniques, a combination thereof, or the like. A thin barrier layer may be conformally deposited in the recesses, such as by chemical vapor deposition (CVD), atomic layer deposition (ALD), physical vapor deposition (PVD), thermal oxidation, a combination thereof, or the like. The barrier layer may be formed from an oxide, a nitride, combinations thereof, or the like. A conductive material may be deposited over the barrier layer and in the recesses. The conductive material may be formed by an electro-chemical plating process, CVD, ALD, PVD, a combination thereof, or the like. Examples of conductive materials include copper, tungsten, aluminum, silver, gold, a combination thereof, or the like. Excess conductive material and barrier layer is removed from a surface of the interconnect structure 54 or the semiconductor substrate 52 by, for example, a chemical-mechanical polish (CMP). The remaining portions of the barrier layer and conductive material in the recesses form the conductive vias 60. After their initial formation, the conductive vias 60 may be buried in the semiconductor substrate 52. The semiconductor substrate 52 may be thinned in subsequent processing to expose the conductive vias 60 at the inactive surface of the semiconductor substrate 52. After the exposure process, the conductive vias 60 are through-substrate vias (TSVs), such as through-silicon vias, that extend through the semiconductor substrate 52.

In this embodiment, the conductive vias 60 are formed by a via-middle process, such that the conductive vias 60 extend through a portion of the interconnect structure 54 (e.g., a subset of the dielectric layers 58) and extend into the semiconductor substrate 52. The conductive vias 60 formed by a via-middle process are connected to a middle metallization pattern 56 of the interconnect structure 54. In another embodiment, the conductive vias 60 are formed by a via-first process, such that the conductive vias 60 extend into the semiconductor substrate 52 but not the interconnect structure 54. The conductive vias 60 formed by a via-first process are connected to a lower metallization pattern 56 of the interconnect structure 54. In yet another embodiment, the conductive vias 60 are formed by a via-last process, such that the conductive vias 60 extend through an entirety of the interconnect structure 54 (e.g., each of the dielectric layers 58) and extend into the semiconductor substrate 52. The conductive vias 60 formed by a via-last process are connected to an upper metallization pattern 56 of the interconnect structure 54.

A dielectric layer 62 is over the interconnect structure 54, at the front-side of the integrated circuit die 50. The dielectric layer 62 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a benzocyclobutene (BCB) based polymer, or the like; a combination thereof; or the like. The dielectric layer 62 may be formed, for example, by CVD, spin coating, lamination, or the like. In some embodiments, the dielectric layer 62 is formed of TEOS-based silicon oxide. Optionally, one or more passivation layer(s) (not separately illustrated) are disposed between the dielectric layer 62 and the interconnect structure 54.

Die connectors 64 extend through the dielectric layer 62. The die connectors 64 may include conductive pillars, pads, or the like, to which external connections can be made. In some embodiments, the die connectors 64 include bond pads at the front-side of the integrated circuit die 50, and include bond pad vias that connect the bond pads to the upper metallization pattern 56 of the interconnect structure 54. In such embodiments, the die connectors 64 (including the bond pads and the bond pad vias) may be formed by a damascene process, such as a single damascene process, a dual damascene process, or the like. The die connectors 64 may be formed of a suitable conductive material, such as copper, tungsten, aluminum, silver, gold, a combination thereof, or the like, which can be formed by, for example, plating or the like.

Optionally, solder regions (not separately illustrated) may be formed on the die connectors 64 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 64. Chip probe testing may be performed on the integrated circuit die 50 to ascertain whether the integrated circuit die 50 is a known good die (KGD). Thus, only integrated circuit dies 50, which are KGDs, undergo subsequent processing, and dies which fail the chip probe testing are not subsequently processed. After testing, the solder regions may be removed. In some embodiments, a planarization process such as a chemical mechanical polish (CMP), an etch-back process, combinations thereof, or the like is utilized.

In some embodiments, the integrated circuit die 50 is a stacked device that includes multiple semiconductor substrates 52. For example, the integrated circuit die 50 may be a memory device that includes multiple memory dies such as a hybrid memory cube (HMC) device, a high bandwidth memory (HBM) device, or the like. In such embodiments, the integrated circuit die 50 includes multiple semiconductor substrates 52 interconnected by TSVs. Each of the semiconductor substrates 52 may (or may not) have a separate interconnect structure 54.

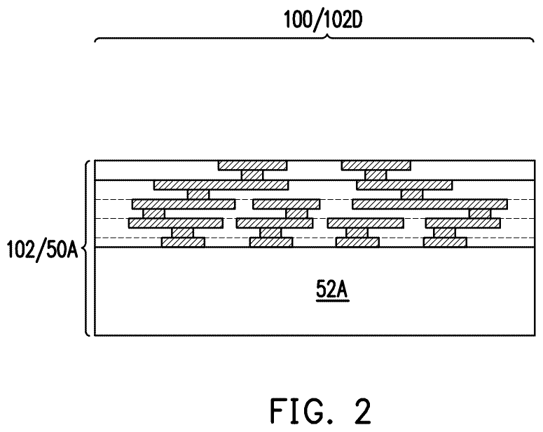

FIGS. 2-11 are cross-sectional views of intermediate stages in the manufacturing of a die structure 100, in accordance with some embodiments. The die structure 100 is a stack of integrated circuit dies 50 (including a lower integrated circuit die 50A and an upper integrated circuit die 50B). The die structure 100 will be formed by bonding the upper integrated circuit die 50B to a wafer 102 that includes the lower integrated circuit die 50A. Bonding of one upper integrated circuit die 50B in one device region 102D of the wafer 102 is illustrated, but it should be appreciated that the wafer 102 may have any number of device regions, and any quantity of upper integrated circuit dies 50B may be bonded in each device region. The device region 102D will be singulated to form the die structure 100.

The die structure 100 is a component that may be subsequently packaged to form an integrated circuit package. The integrated circuit dies 50 of the die structure 100 may be heterogeneous dies. Packaging the die structure 100 in lieu of packaging the dies individually may allow heterogeneous dies to be integrated with a smaller footprint. The die structure 100 may be a system-on-integrated-chips (SoIC) device, although other types of devices may be formed.

In FIG. 2, the wafer 102 is obtained. The wafer 102 includes a lower integrated circuit die 50A in the device region 102D, which will be singulated in subsequent processing to be included in the die structure 100. The lower integrated circuit die 50A has a similar structure to that described for FIG. 1, except the lower integrated circuit die 50A does not include conductive vias that extend into the semiconductor substrate 52A of the lower integrated circuit die 50A. In some embodiments, the lower integrated circuit die 50A is a logic die (previously described).

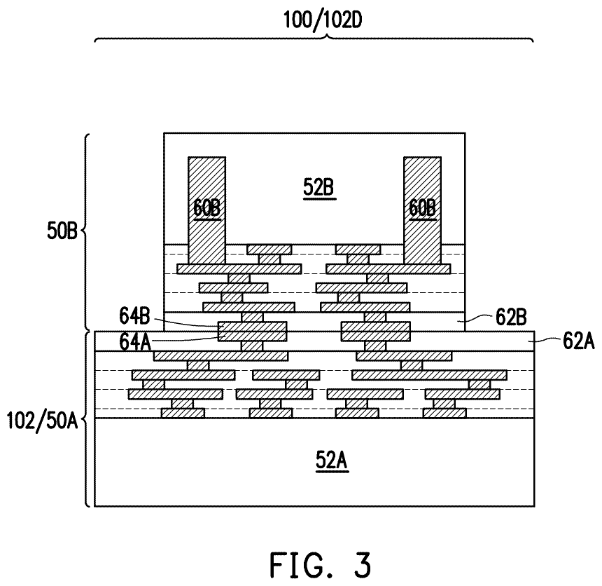

In FIG. 3, an upper integrated circuit die 50B is attached to the lower integrated circuit die 50A (e.g., to the wafer 102). The upper integrated circuit die 50B has a similar structure to that described for FIG. 1. In some embodiments, the upper integrated circuit die 50B is a memory die, a power management die, or the like (previously described). The function of the upper integrated circuit die 50B may (or may not) be different than the function of the lower integrated circuit die 50A. The lower integrated circuit die 50A and the upper integrated circuit die 50B may be formed in processes of a same technology node, or may be formed in processes of different technology nodes. For example, the lower integrated circuit die 50A may be of a more advanced process node than the upper integrated circuit die 50B. The lower integrated circuit die 50A is wider than the upper integrated circuit die 50B.

The upper integrated circuit die 50B may be attached to the lower integrated circuit die 50A by placing the upper integrated circuit die 50B on the lower integrated circuit die 50A (e.g., on the wafer 102) and then bonding the upper integrated circuit die 50B to the lower integrated circuit die 50A. The upper integrated circuit die 50B may be placed by, e.g., a pick-and-place process. The bonding process may include fusion bonding, dielectric bonding, metal bonding, a combination thereof (e.g., a combination of dielectric-to-dielectric bonding and metal-to-metal bonding), or the like. As an example of the bonding process, the upper integrated circuit die 50B may be bonded to the lower integrated circuit die 50A by a combination of dielectric-to-dielectric bonding and metal-to-metal bonding. The dielectric layer 62B of the upper integrated circuit die 50B is directly bonded to the dielectric layer 62A of the lower integrated circuit die 50A through dielectric-to-dielectric bonding, without using any adhesive material (e.g., die attach film). The die connectors 64B of the upper integrated circuit die 50B are directly bonded to respective die connectors 64A of the lower integrated circuit die 50A through metal-to-metal bonding, without using any eutectic material (e.g., solder). The bonding may include a pre-bonding and an annealing. During the pre-bonding, a small pressing force is applied to press the upper integrated circuit die 50B (e.g., the dielectric layer 62B) against the lower integrated circuit die 50A (e.g., the dielectric layer 62A). The pre-bonding is performed at a low temperature, such as about room temperature, and after the pre-bonding, the dielectric layer 62A is bonded to the dielectric layer 62B. The bonding strength is then improved in a subsequent annealing process, in which the dielectric layers 62A, 62B and the die connectors 64A, 64B are annealed. After the annealing, direct bonds such as fusion bonds are formed, bonding the dielectric layer 62A to the dielectric layer 62B. For example, the bonds can be covalent bonds between the material of the dielectric layer 62A and the material of the dielectric layer 62B. The die connectors 64A are connected to the die connectors 64B with a one-to-one correspondence. The die connectors 64A and the die connectors 64B may be in physical contact after the pre-bonding, or may expand to be brought into physical contact during the annealing. Further, during the annealing, the material(s) of the die connectors 64A and the die connectors 64B (e.g., copper) intermingles, so that metal-to-metal bonds are also formed. Hence, the resulting bonds between the lower integrated circuit die 50A and the upper integrated circuit die 50B include both dielectric-to-dielectric bonds and metal-to-metal bonds.

The upper integrated circuit die 50B is attached to the lower integrated circuit die 50A in a face-to-face manner. In some embodiments, the upper integrated circuit die 50B is face-to-face bonded to the lower integrated circuit die 50A. As such, the front-side of the lower integrated circuit die 50A faces towards the front-side of the upper integrated circuit die 50B. The back-side of the lower integrated circuit die 50A faces away from the back-side of the upper integrated circuit die 50B.

The semiconductor substrate 52B of the upper integrated circuit die 50B is optionally thinned, which can help reduce the overall thickness of the die structure 100. The thinning process may be, for example, a chemical-mechanical polish (CMP), a grinding process, an etch-back process, or the like, which is performed at the back-side of the upper integrated circuit die 50B. The thinning process reduces the thickness of the semiconductor substrate 52A. The conductive vias 60B of the upper integrated circuit die 50B remain buried by the semiconductor substrate 52B after this thinning process. Thinning the semiconductor substrate 52B at this step of processing can help reduce the costs of exposing the conductive vias 60B in subsequent processing steps.

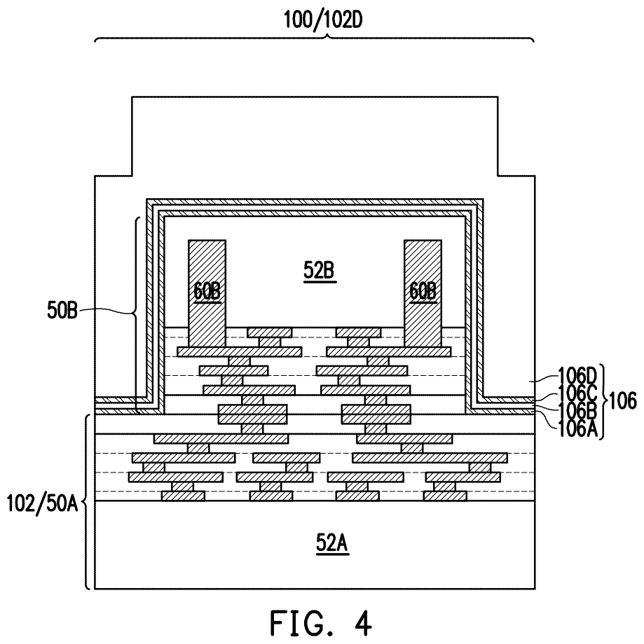

In FIG. 4, a gap-fill dielectric 106 is formed around the upper integrated circuit die 50B and on the lower integrated circuit die 50A. Initially, the gap-fill dielectric 106 may be formed on the upper integrated circuit die 50B and the lower integrated circuit die 50A, such that the gap-fill dielectric 106 buries or covers the upper integrated circuit die 50B. Accordingly, the top surface of the gap-fill dielectric 106 may initially be above the top surface of the upper integrated circuit die 50B. The gap-fill dielectric 106 is disposed over the portions of the lower integrated circuit die 50A (e.g., the wafer 102) adjacent the upper integrated circuit die 50B, and may contact the top surface of the lower integrated circuit die 50A. The gap-fill dielectric 106 is a dielectric filler (or dielectric feature) that fills (and may overfill) the gaps between the upper integrated circuit die 50B and upper integrated circuit dies 50B in other device regions (not separately illustrated). The gap-fill dielectric 106 may be formed of one or more dielectric materials. Acceptable gap-fill dielectric materials include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like.

In some embodiments, the gap-fill dielectric 106 is multi-layered including one or more liner layer(s) and a main layer. In this embodiment, the gap-fill dielectric 106 includes a first liner 106A, a second liner 106B, a third liner 106C, and a main filler 106D. The gap-fill dielectric 106 may have a nitride-oxide-nitride-oxide (NONO) structure, in which the first liner 106A and the third liner 106C are formed of nitrides (previously described), and in which the second liner 106B and the main filler 106D are formed of oxides (previously described). For example, the first liner 106A and the third liner 106C may be nitride liners formed of silicon nitride, the second liner 106B may be an oxide liner formed of silicon oxide, and the main filler 106D may be an oxide filler formed of silicon oxide. Utilizing an NONO structure may reduce the risk of damaging the integrated circuit dies 50 when forming the gap-fill dielectric 106. For example, cracking of the gap-fill dielectric 106 along the edges of the upper integrated circuit die 50B may be avoided when an NONO structure is formed.

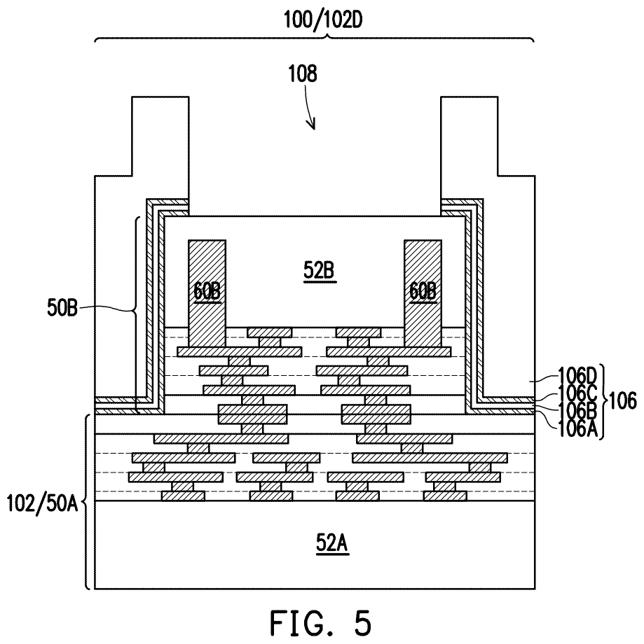

In FIG. 5, a portion of the gap-fill dielectric 106 above the upper integrated circuit die 50B may optionally be removed to form an opening 108. The portion of the gap-fill dielectric 106 above the upper integrated circuit die 50B may be removed by suitable photolithography and etching techniques. The opening 108 may expose the back-side of the upper integrated circuit die 50B. Removing a portion of the gap-fill dielectric 106 by etching may reduce pattern loading effects during a subsequent process for planarizing the gap-fill dielectric 106.

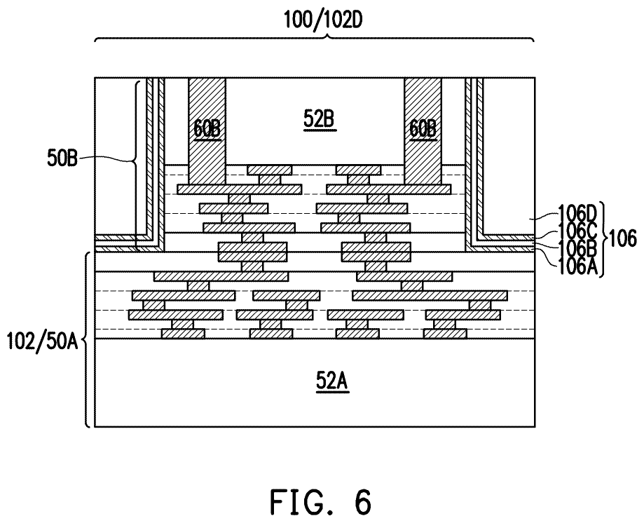

In FIG. 6, a removal process is performed to level surfaces of the gap-fill dielectric 106 with the back-side of the upper integrated circuit die 50B (e.g., the inactive surface of the semiconductor substrate 52B). The remaining portions of the gap-fill dielectric 106 above the upper integrated circuit die 50B are removed. In some embodiments, a planarization process such as a chemical mechanical polish (CMP), an etch-back process, combinations thereof, or the like is utilized.

Additionally, the semiconductor substrate 52B is thinned to expose the conductive vias 60B. Portions of the gap-fill dielectric 106 may also be removed by the thinning process. The thinning process may be, for example, a chemical-mechanical polish (CMP), a grinding process, an etch-back process, the like, or a combination thereof, which is performed at the back-side of the integrated circuit die 50B. The planarization process may be performed until the top surfaces of the gap-fill dielectric 106 and the upper integrated circuit die 50B (including surfaces of the semiconductor substrate 52B and the conductive vias 60B) are substantially coplanar (within process variations). The thinning process for the semiconductor substrate 52B may (or may not) be different than the removal process for the gap-fill dielectric 106. After the exposure process, the conductive vias 60B are through-substrate vias (TSVs) that extend through the semiconductor substrate 52B.

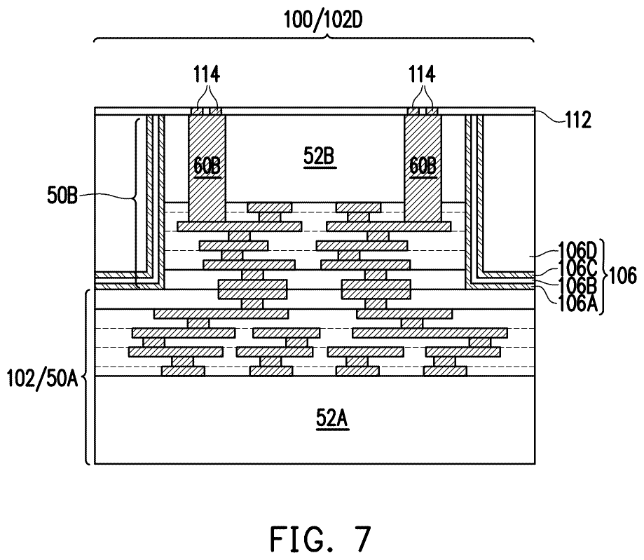

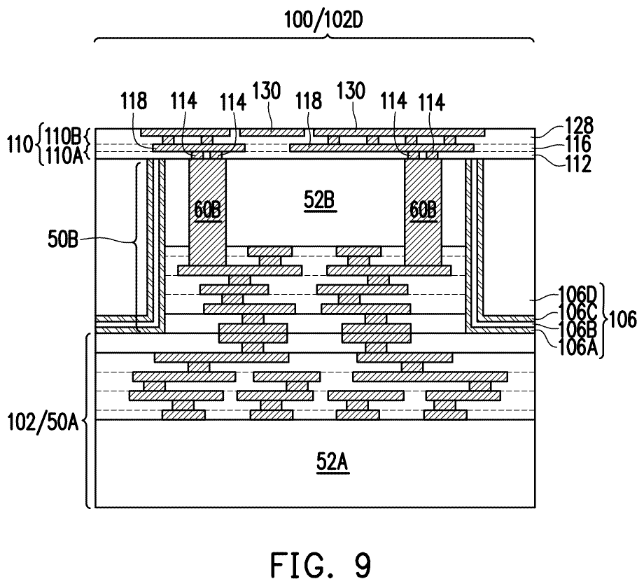

As subsequently described for FIGS. 7-9, a back-side interconnect structure 110 (see FIG. 9) will be formed on the coplanar top surfaces of the gap-fill dielectric 106 and the upper integrated circuit die 50B. The back-side interconnect structure 110 includes dielectric layers and conductive features in the dielectric layers. The conductive features are interconnects that are electrically coupled to the devices of the integrated circuit dies 50 (including the lower integrated circuit die 50A and the upper integrated circuit die 50B). Specifically, the conductive features of the back-side interconnect structure 110 are coupled to the integrated circuit dies 50 through the conductive vias 60B.

A lower portion 110A (e.g., small-featured portion) of the back-side interconnect structure 110 will be formed by single damascene processes. An upper portion 110B (e.g., large-featured portion) of the back-side interconnect structure 110 will be formed by dual damascene processes. The conductive features of the lower portion 110A of the back-side interconnect structure 110 are smaller than the conductive features of the upper portion 110B of the back-side interconnect structure 110.

In FIG. 7, a dielectric layer 112 is formed on the coplanar top surfaces of the gap-fill dielectric 106 and the upper integrated circuit die 50B. The dielectric layer 112 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layer 112 may be formed of a low-k dielectric material having a k-value lower than about 3.0. The dielectric layer 112 may be formed of an extra-low-k (ELK) dielectric material having a k-value of less than 2.5.

Conductive vias 114 are formed in the dielectric layer 112. The conductive vias 114 extend through the dielectric layer 112 to contact the conductive vias 60B. The conductive vias 114 may be formed by a damascene process, specifically, a single damascene process. As an example to form the conductive vias 114, the dielectric layer 112 is patterned utilizing photolithography and etching techniques to form openings corresponding to the desired pattern of the conductive vias 114. The openings may then be filled with a conductive material. Suitable conductive materials include copper, silver, gold, tungsten, aluminum, combinations thereof, or the like, which may be formed by electroplating or the like. A removal process may be performed to remove excess conductive material from a surface of the dielectric layer 112. In some embodiments, a planarization process such as a chemical mechanical polish (CMP), an etch-back process, combinations thereof, or the like is utilized. The remaining conductive material forms the conductive vias 114 in the openings.

A plurality of conductive vias 114 are electrically and physically coupled to each conductive via 60B. Each conductive via 114 is smaller (e.g., narrower) than the underlying conductive via 60B. More specifically, the critical dimension (e.g., width) of the conductive vias 114 is less than the critical dimension (e.g., width) of the conductive vias 60B. In some embodiments, the critical dimension of the conductive vias 114 is in the range of 0.2 μm to 2 μm and the critical dimension of the conductive vias 60B is in the range of 1 μm to 5 μm. In some embodiments, a width of each conductive via 114 is less than half a width of the underlying conductive via 60B. Forming the conductive vias 114 smaller than the conductive vias 60B helps reduce the risk of the conductive vias 114 contacting the semiconductor substrate 52B. As a result, the conductive vias 114 are spaced apart from the semiconductor substrate 52B by dielectric materials.

The conductive vias 114 are formed on the conductive vias 60B in lieu of recessing the semiconductor substrate 52B so that the conductive vias 60B protrude from the inactive surface of the semiconductor substrate 52B. Vertical connections to overlying conductive lines may thus be achieved without recessing the semiconductor substrate 52B. When the gap-fill dielectric 106 has a nitride-oxide-nitride-oxide structure, omitting the recessing of the semiconductor substrate 52B may avoid etching of the first liner 106A and the third liner 106C (e.g., nitrides), thereby reducing pin hole defects in the die structure 100. Reducing pin hole defects can improve the yield and reliability of the die structure 100.

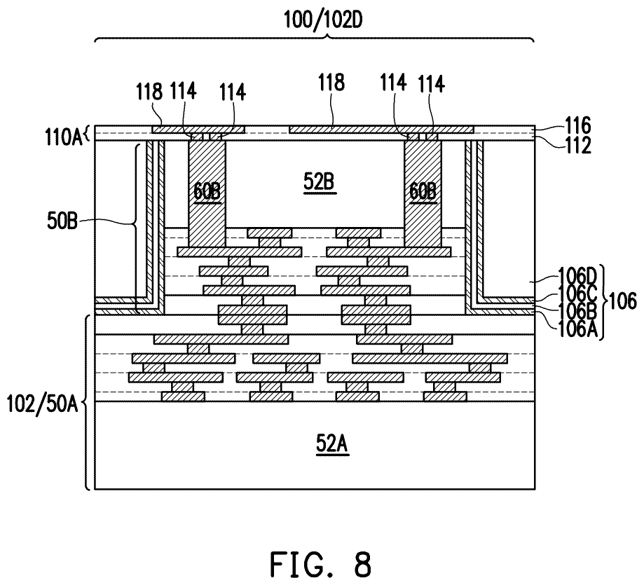

In FIG. 8, a dielectric layer 116 is formed on the conductive vias 114 and the dielectric layer 112. The dielectric layer 116 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layer 116 may be formed of a low-k dielectric material having a k-value lower than about 3.0. The dielectric layer 116 may be formed of an extra-low-k (ELK) dielectric material having a k-value of less than 2.5.

Conductive lines 118 are formed in the dielectric layer 116. The conductive lines 118 extend through the dielectric layer 116 to contact the conductive vias 114, and extend along the dielectric layer 112. The conductive lines 118 may be formed by a damascene process, specifically, a single damascene process. As an example to form the conductive lines 118, the dielectric layer 116 is patterned utilizing photolithography and etching techniques to form openings corresponding to the desired pattern of the conductive lines 118. The openings may then be filled with a conductive material. Suitable conductive materials include copper, silver, gold, tungsten, aluminum, combinations thereof, or the like, which may be formed by electroplating or the like. A removal process may be performed to remove excess conductive material from a surface of the dielectric layer 116. In some embodiments, a planarization process such as a chemical mechanical polish (CMP), an etch-back process, combinations thereof, or the like is utilized. The remaining conductive material forms the conductive lines 118 in the openings.

In FIG. 9, a dielectric layer 128 is formed on the conductive lines 118 and the dielectric layer 116. The dielectric layer 128 may be formed of a dielectric material. Acceptable dielectric materials include silicon oxide, phosphosilicate glass (PSG), borosilicate glass (BSG), boron-doped phosphosilicate glass (BPSG), or the like, which may be formed by CVD, ALD, or the like. The dielectric layer 128 may be formed of a low-k dielectric material having a k-value lower than about 3.0. The dielectric layer 128 may be formed of an extra-low-k (ELK) dielectric material having a k-value of less than 2.5.

Conductive features 130 are formed in the dielectric layer 128. The conductive features 130 may include conductive lines and vias in the dielectric layer 128, with each combination of a conductive via and an overlying conductive line extending through the dielectric layer 128. The conductive features 130 extend through the dielectric layer 128 to contact the conductive lines 118. The conductive features 130 may be formed by a damascene process, specifically, a dual damascene process. As an example to form the conductive features 130, the dielectric layer 128 is patterned utilizing photolithography and etching techniques to form interconnect openings (including trenches and via openings) corresponding to the desired pattern of the conductive features 130. The interconnect openings may then be filled with a conductive material. Suitable conductive materials include copper, silver, gold, tungsten, aluminum, combinations thereof, or the like, which may be formed by electroplating or the like. A removal process may be performed to remove excess conductive material from a surface of the dielectric layer 128. In some embodiments, a planarization process such as a chemical mechanical polish (CMP), an etch-back process, combinations thereof, or the like is utilized. The remaining conductive material forms the conductive features 130 in the interconnect openings.

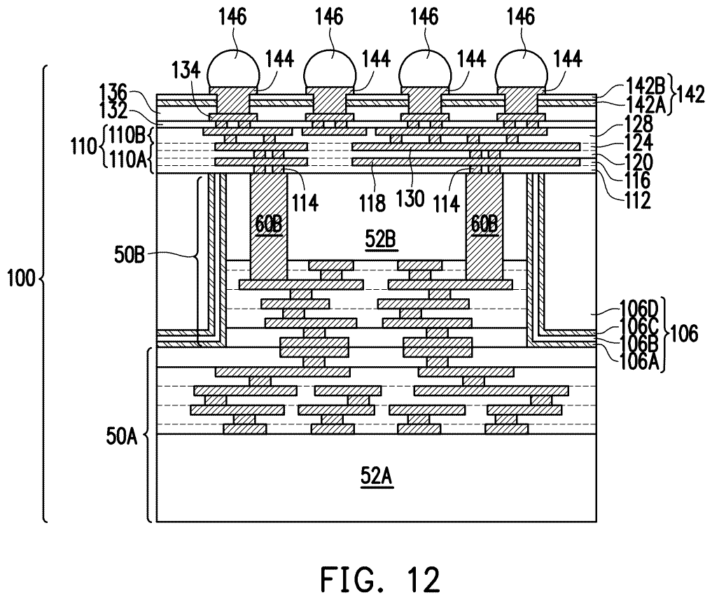

The back-side interconnect structure 110 may include any desired number of layers of the conductive features. In this embodiment, the lower portion 110A of the back-side interconnect structure 110 includes one layer of conductive lines and vias (e.g., the conductive vias 114 and the conductive lines 118) in the dielectric layers 112, 116. Similarly, the upper portion 110B of the back-side interconnect structure 110 includes one layer of conductive lines and vias (e.g., the conductive features 130) in the dielectric layer 128. In another embodiment (subsequently described for FIG. 12), the lower portion 110A and/or upper portion 110B of the back-side interconnect structure 110 includes multiple layers of conductive lines and vias.

As previously noted, the conductive features of the lower portion 110A of the back-side interconnect structure 110 are formed by a single damascene process, while the conductive features of the upper portion 110B of the back-side interconnect structure 110 are formed by a dual damascene process. Utilizing a single damascene process to form the conductive vias 114 can increase the accuracy of the conductive vias 114 landing on the conductive vias 60B. Utilizing a dual damascene process to form the conductive features 130 can reduce manufacturing costs. Other variations are contemplated. In another embodiment, both the lower portion 110A and the upper portion 110B of the back-side interconnect structure 110 are formed by a dual damascene process.

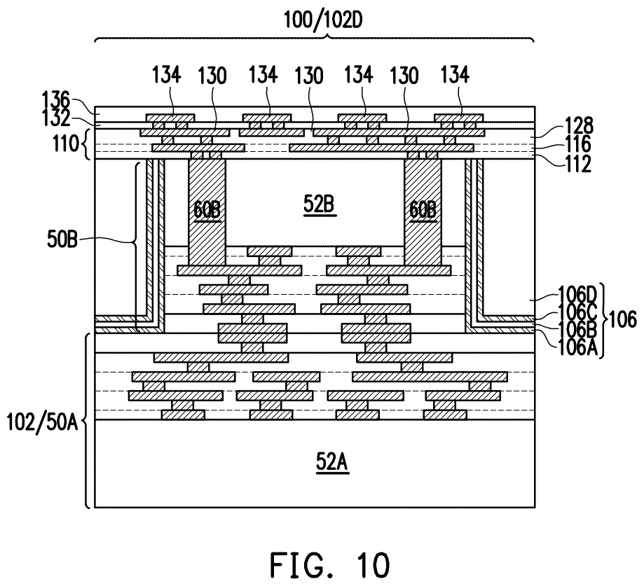

In FIG. 10, one or more passivation layer(s) 132 are formed on the back-side interconnect structure 110. The passivation layer(s) 132 may be formed of one or more suitable dielectric materials such as silicon oxynitride, silicon nitride, low-k dielectrics such as carbon doped oxides, extremely low-k dielectrics such as porous carbon doped silicon oxide, or the like; a polymer such as polyimide, solder resist, polybenzoxazole (PBO), a benzocyclobutene (BCB) based polymer, molding compound, or the like; a combination thereof; or the like. The passivation layer(s) 132 may be formed by CVD, spin coating, lamination, the like, or a combination thereof.

Conductive pads 134 are formed extending through the passivation layer(s) 132 to electrically and physically couple to the upper conductive features 130 of the back-side interconnect structure 110. The conductive pads 134 may be formed by a damascene process, such as a single damascene process. The conductive pads 134 may be formed of a suitable conductive material, such as copper, tungsten, aluminum, silver, gold, a combination thereof, or the like, which can be formed by, for example, plating or the like. In some embodiments, the conductive pads 134 are formed of a low-cost conductive material (e.g., aluminum).

A dielectric layer 136 is formed on the conductive pads 134 and the passivation layer(s) 132. The dielectric layer 136 may bury or cover the conductive pads 134. The dielectric layer 136 may be formed of a polymer such as PBO, polyimide, a BCB-based polymer, or the like; a nitride such as silicon nitride or the like; an oxide such as silicon oxide, phosphosilicate glass (PSG), borosilicate glass (BSG), boron-doped phosphosilicate glass (BPSG), a tetraethyl orthosilicate (TEOS) based oxide; the like, or a combination thereof. The dielectric layer 136 may be formed, for example, by spin coating, lamination, CVD, or the like.

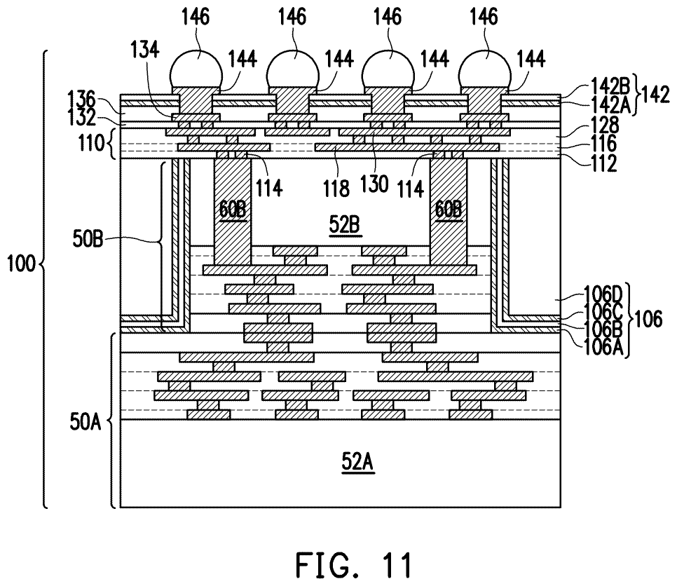

In FIG. 11, a singulation process is performed along scribe line regions, e.g., between the device region 102D and adjacent device regions (not separately illustrated). The singulation process may include performing a sawing process, a laser cutting process, or the like on the wafer 102, the gap-fill dielectric 106, the back-side interconnect structure 110, the passivation layer(s) 132, and the dielectric layer 136. The singulation process separates the device region 102D (including the lower integrated circuit die 50A) from the adjacent device regions of the wafer 102. The resulting, singulated die structure 100 is from the device region 102D. After the singulation process, the lower integrated circuit die 50A, the gap-fill dielectric 106, the back-side interconnect structure 110, the passivation layer(s) 132, and the dielectric layer 136 are laterally coterminous.

The die structure 100 is a component that may be subsequently implemented in an integrated circuit package. The integrated circuit dies 50 of the die structure 100 may be heterogeneous dies. Packaging the die structure 100 in lieu of or in addition to packaging dies individually may allow heterogeneous dies to be integrated with a smaller footprint. In some embodiments, an integrated circuit package is formed by encapsulating the die structure 100 and forming redistribution lines on the encapsulant to fan-out connections from the die structure 100. In some embodiments, an integrated circuit package is formed by attaching the die structure 100 to an additional component, such as an interposer, a packing substrate, or the like.

The die structure 100 may include additional features for attaching the die structure 100 to an additional component. In this embodiment, the die structure 100 further includes one or more dielectric layer(s) 142, die connectors 144, and conductive connectors 146. The conductive connectors 146 may be used to connect the die structure 100 (e.g., the die connectors 144) to the additional component. The dielectric layer(s) 142, the die connectors 144, and the conductive connectors 146 may be formed before or after the die structure 100 is singulated.

The dielectric layer(s) 142 may be formed on the dielectric layer 136. The dielectric layer(s) 142 may be formed of one or more suitable dielectric materials such as silicon oxynitride, silicon nitride, low-k dielectrics such as carbon doped oxides, extremely low-k dielectrics such as porous carbon doped silicon oxide, a polymer such as polyimide, solder resist, polybenzoxazole (PBO), a benzocyclobutene (BCB) based polymer, molding compound, the like, or a combination thereof. The dielectric layer(s) 142 may be formed by chemical vapor deposition (CVD), spin coating, lamination, the like, or a combination thereof. In some embodiments, the dielectric layer(s) 142 include a lower dielectric layer 142A formed of a nitride (e.g., silicon nitride) and an upper dielectric layer 142B formed of a polymer (e.g., polyimide).

The die connectors 144 may be formed through the dielectric layer(s) 142 and the dielectric layer 136 to contact the conductive pads 134. The die connectors 144 may include conductive pillars, pads, or the like, to which external connections can be made. The die connectors 144 can be formed of a conductive material, such as a metal, such as copper, aluminum, or the like, which can be formed by, for example, plating, or the like.

As an example to form the die connectors 144, the dielectric layer(s) 142 and the dielectric layer 136 are patterned utilizing photolithography and etching techniques to form openings corresponding to the desired pattern of the die connectors 144. In some embodiments, the dielectric layer(s) 142 are used as masking layers during the patterning of the openings. For example, the upper dielectric layer 142B may be patterned by an acceptable process, such as by exposing the upper dielectric layer 142B to light when the upper dielectric layer 142B is a photosensitive material or by etching using, for example, an anisotropic etch. If the upper dielectric layer 142B is a photosensitive material, the upper dielectric layer 142B can be developed after the exposure. The lower dielectric layer 142A may then be patterned by etching the lower dielectric layer 142A using the upper dielectric layer 142B as an etching mask. The lower dielectric layer 142A may then be used as an etching mask (e.g., a hard mask) to etch the dielectric layer 136. The openings may then be filled with a conductive material (previously described) to form the die connectors 144 in the openings.

The conductive connectors 146 may be formed on the die connectors 144. The conductive connectors 146 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 146 may include a conductive material such as solder, copper, aluminum, gold, nickel, silver, palladium, tin, the like, or a combination thereof. In some embodiments, the conductive connectors 146 are formed by initially forming a layer of a reflowable material (e.g., solder) through evaporation, electroplating, printing, solder transfer, ball placement, or the like. Once a layer of solder has been formed on the structure, a reflow may be performed in order to shape the material into the desired bump shapes.

FIG. 12 is a cross-sectional view of a die structure 100, in accordance with some embodiments. This embodiment is similar to the embodiment of FIG. 11, except the lower portion 110A of the back-side interconnect structure 110 further includes dielectric layers 120, 124 and an additional layer of conductive lines and vias. Specifically, the lower portion 110A of the back-side interconnect structure 110 includes two layers of conductive lines and vias (e.g., conductive vias 114, 122 and conductive lines 118, 126) in the dielectric layers 112, 116, 120, 124.

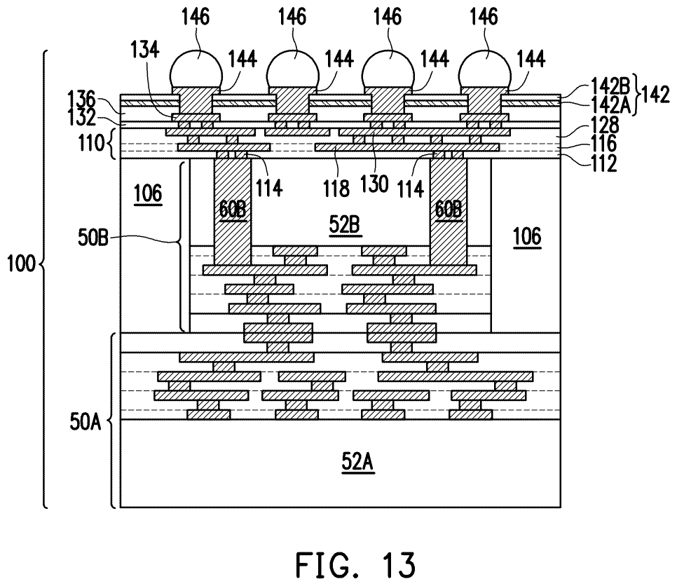

FIG. 13 is a cross-sectional view of a die structure 100, in accordance with some embodiments. This embodiment is similar to the embodiment of FIG. 11, except the gap-fill dielectric 106 includes an epoxy material in lieu of a nitride-oxide-nitride-oxide (NONO) structure. The epoxy material may be a molding compound, an underfill, or the like. When a molding compound is used, it may be applied by compression molding, transfer molding, or the like. When an underfill is used, it may be applied by a capillary flow process, a deposition process, or the like.

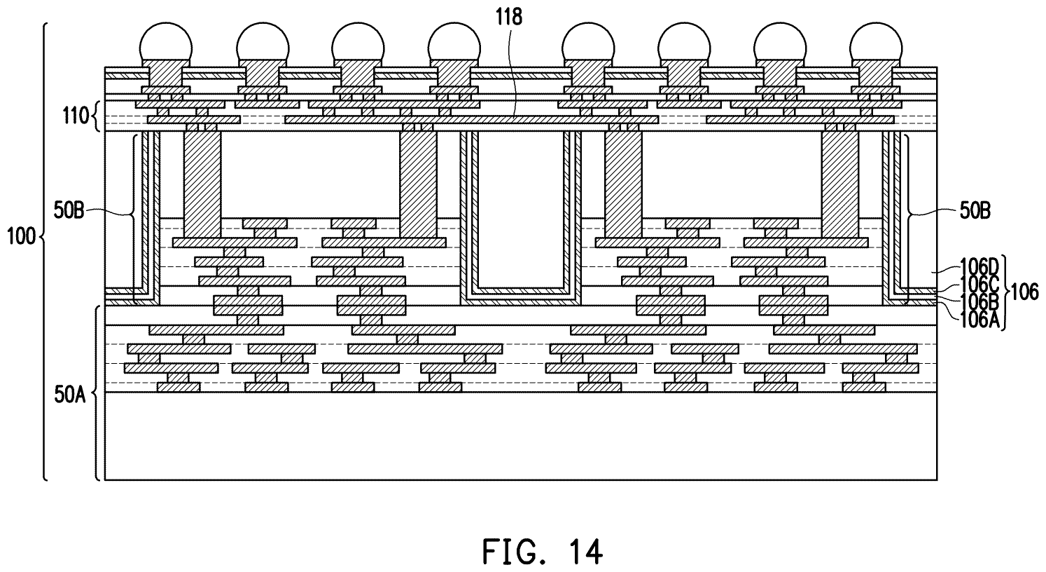

FIG. 14 is a cross-sectional view of a die structure 100, in accordance with some embodiments. This embodiment is similar to the embodiment of FIG. 11, except multiple upper integrated circuit dies 50B are bonded to the lower integrated circuit die 50A. The gap-fill dielectric 106 fills the gap(s) between the upper integrated circuit dies 50B. The upper integrated circuit dies 50B may be interconnected at least in part by some of the conductive lines 118.

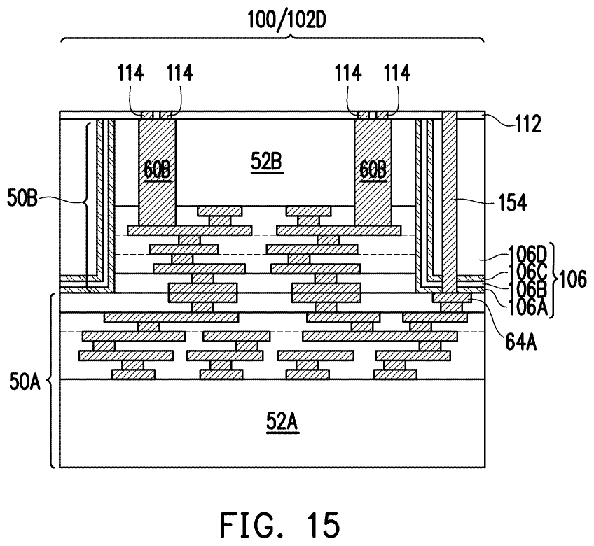

FIGS. 15-17 are cross-sectional views of intermediate stages in the manufacturing of a die structure 100, in accordance with some embodiments. In this embodiment, the die structure 100 includes through-dielectric vias (TDVs) that extend through dielectric materials to help connect the lower integrated circuit die 50A to the conductive features of the back-side interconnect structure 110. The TDVs may be formed during the formation of the back-side interconnect structure 110.

In FIG. 15, the structure of FIG. 7 is obtained. Conductive vias 154 are formed through the gap-fill dielectric 106 and the dielectric layer 112. The conductive vias 154 may be formed after the conductive vias 114. Each conductive via 154 contacts a die connector 64A. The conductive vias 154 are through-dielectric vias (TDVs) that extend through dielectric materials.

As an example to form the conductive vias 154, the gap-fill dielectric 106 and the dielectric layer 112 are patterned utilizing photolithography and etching techniques to form openings corresponding to the desired pattern of the conductive vias 154. The openings expose a subset of the die connectors 64A of the lower integrated circuit die 50A. A seed layer is formed on the dielectric layer 112 and on portions of the die connectors 64A exposed by the openings. In some embodiments, the seed layer is a metal layer, which may be a single layer or a composite layer including a plurality of sub-layers formed of different materials. In a particular embodiment, the seed layer includes a titanium layer and a copper layer over the titanium layer. The seed layer may be formed using, for example, PVD or the like. A conductive material is formed on the seed layer. The conductive material may be formed by plating, such as electroplating or electroless plating, or the like. The conductive material may include a metal, such as copper, titanium, tungsten, aluminum, or the like. Excess portions of the seed layer and conductive material are then removed from a surface of the gap-fill dielectric 106. In some embodiments, a planarization process such as a chemical mechanical polish (CMP), an etch-back process, combinations thereof, or the like is utilized. The remaining portions of the seed layer and conductive material in the openings form the conductive vias 154.

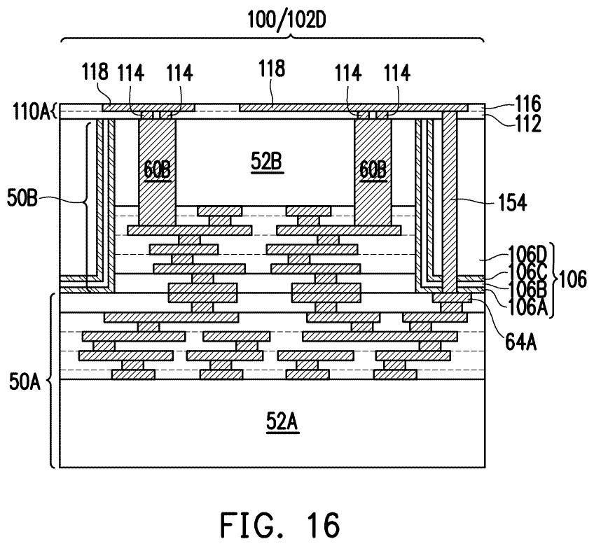

In FIG. 16, a dielectric layer 116 is formed on the conductive vias 154, the conductive vias 114, and the dielectric layer 112. The dielectric layer 116 may be formed in a similar manner as previously described for FIG. 8. Conductive lines 118 are then formed in the dielectric layer 116. A subset of the conductive lines 118 are electrically and physically coupled to the conductive via 154. The conductive lines 118 may be formed in a similar manner as previously described for FIG. 8.

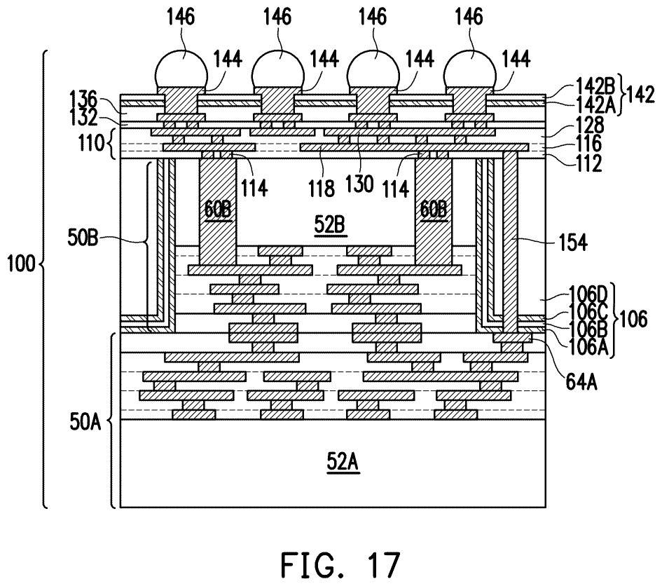

In FIG. 17, appropriate processing as previously described for FIGS. 9-11 is performed to complete the die structure 100. In the die structure 100 of this embodiment, the conductive vias 154 connect the lower integrated circuit die 50A to the conductive features of the back-side interconnect structure 110. The conductive vias 154 extend through the dielectric layer 112 and each layer of the gap-fill dielectric 106.

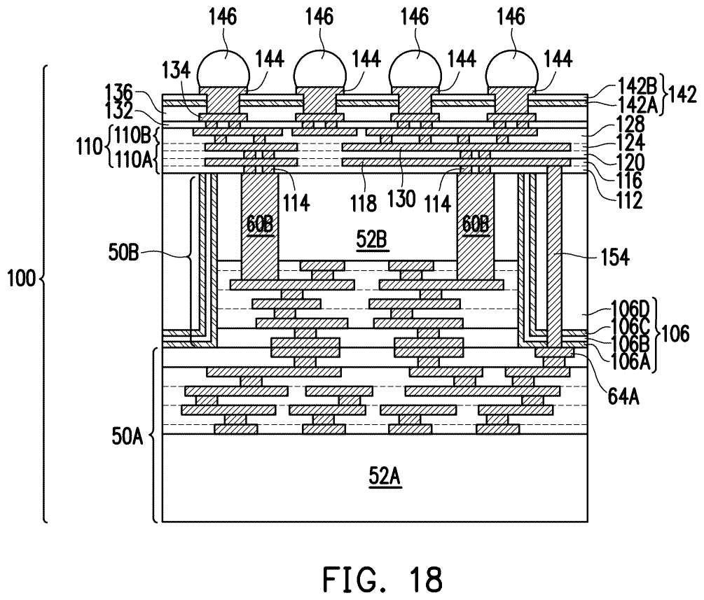

FIG. 18 is a cross-sectional view of a die structure 100, in accordance with some embodiments. This embodiment is similar to the embodiment of FIG. 17, except the lower portion 110A of the back-side interconnect structure 110 further includes dielectric layers 120, 124 and an additional layer of conductive lines and vias. Specifically, the lower portion 110A of the back-side interconnect structure 110 includes two layers of conductive lines and vias (e.g., conductive vias 114, 122 and conductive lines 118, 126) in the dielectric layers 112, 116, 120, 124.

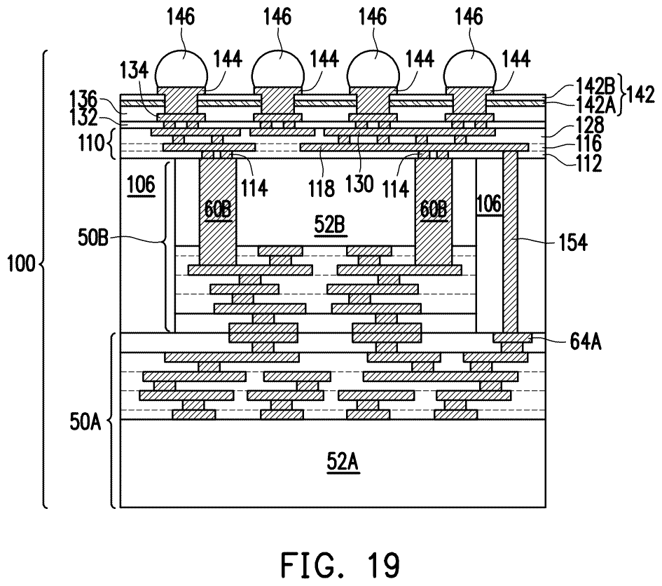

FIG. 19 is a cross-sectional view of a die structure 100, in accordance with some embodiments. This embodiment is similar to the embodiment of FIG. 17, except the gap-fill dielectric 106 includes an epoxy material in lieu of a nitride-oxide-nitride-oxide (NONO) structure. The epoxy material may be a molding compound, an underfill, or the like. When a molding compound is used, it may be applied by compression molding, transfer molding, or the like. When an underfill is used, it may be applied by a capillary flow process, a deposition process, or the like.

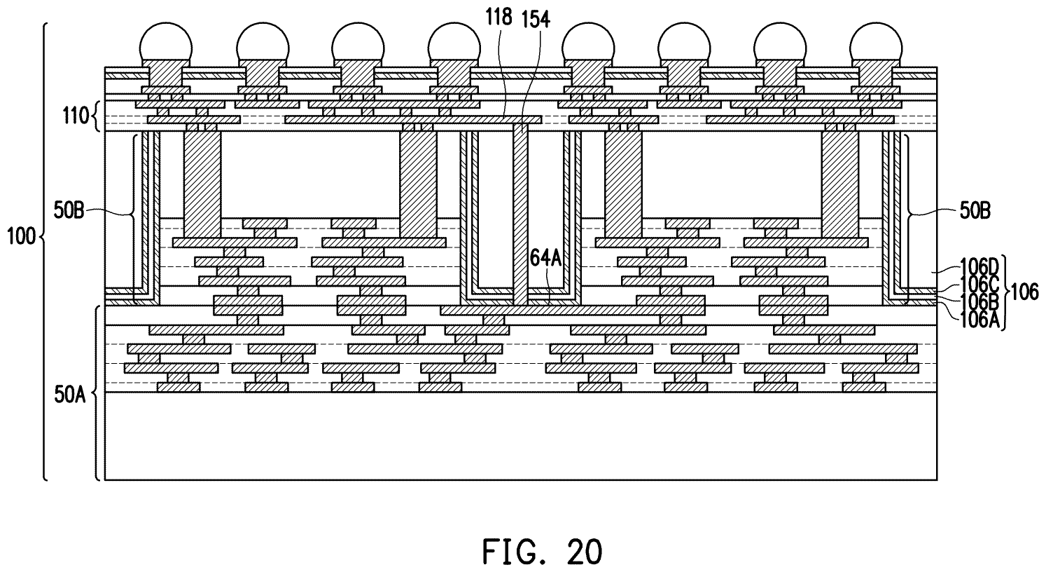

FIG. 20 is a cross-sectional view of a die structure 100, in accordance with some embodiments. This embodiment is similar to the embodiment of FIG. 17, except multiple upper integrated circuit dies 50B are bonded to the lower integrated circuit die 50A. The gap-fill dielectric 106 fills the gap(s) between the upper integrated circuit dies 50B. The upper integrated circuit dies 50B may be interconnected at least in part by some of the conductive lines 118. Additionally, some of the conductive vias 154 may be utilized for interconnecting the upper integrated circuit dies 50B. For example, a conductive via 154 may be used to connect a back-side of an upper integrated circuit die 50B to a front-side of another upper integrated circuit die 50B, through a die connector 64A of the lower integrated circuit die 50A.

Embodiments may achieve advantages. Forming the conductive vias 114 on the conductive vias 60B allows vertical connections to the conductive lines 118 to be achieved without recessing the semiconductor substrate 52B. When the gap-fill dielectric 106 has a nitride-oxide-nitride-oxide structure, omitting the recessing of the semiconductor substrate 52B may avoid etching of the first liner 106A and the third liner 106C (e.g., nitrides), thereby reducing pin hole defects in the die structure 100. Reducing pin hole defects can improve the yield and reliability of the die structure 100.

Other techniques may be used to reduce pin hole defects in the die structure 100. As subsequently described in greater detail, the gap-fill dielectric 106 may be formed in a manner that allows the semiconductor substrate 52B to be recessed while avoiding damage to the liner(s) of the gap-fill dielectric 106. Pin hole defects in the die structure 100 may thus be reduced, even if the semiconductor substrate 52B is recessed so that the conductive vias 60B protrude from the inactive surface of the semiconductor substrate 52B.

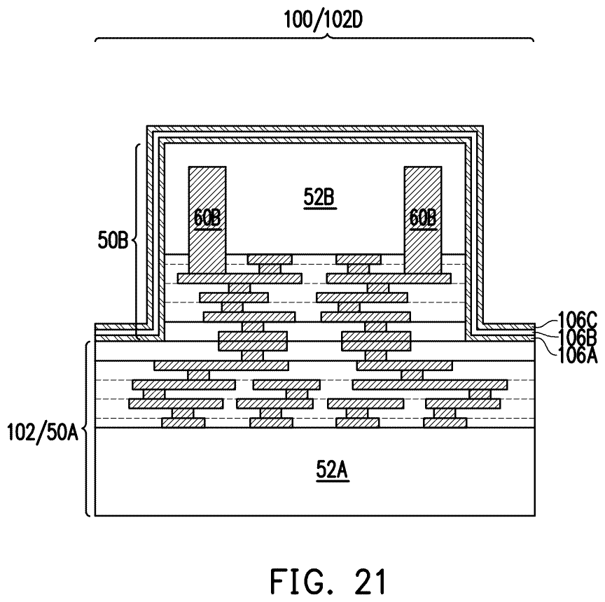

FIGS. 21-26 are cross-sectional views of intermediate stages in the manufacturing of a die structure 100, in accordance with some embodiments. In this embodiment, the main filler 106D is formed to cover the third liner 106C. As such, the main filler 106D may protect the third liner 106C during recessing of the semiconductor substrate 52B.

In FIG. 21, the structure of FIG. 3 is obtained. The liner layer(s) of the gap-fill dielectric 106, e.g., the first liner 106A, the second liner 106B, and the third liner 106C, are then formed around the upper integrated circuit die 50B and on the lower integrated circuit die 50A. The first liner 106A, the second liner 106B, and the third liner 106C may be formed in a similar manner as previously described for FIG. 4.

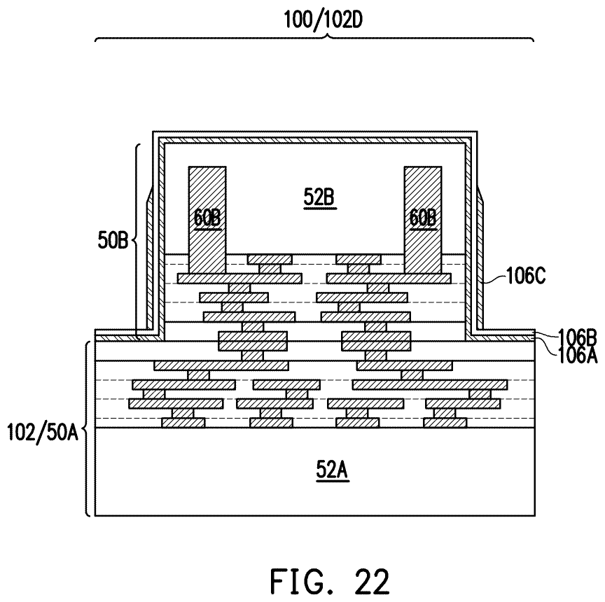

In FIG. 22, the third liner 106C is patterned such that the third liner 106C is recessed. The third liner 106C may be patterned by etching the third liner 106C to remove horizontal portions of the third liner 106C. Any acceptable etch process, such as a dry etch, a wet etch, the like, or a combination thereof, may be performed to pattern the third liner 106C. The etching may be anisotropic. The second liner 106B may be used as an etch stop layer when etching the third liner 106C, such that the horizontal portions of the second liner 106B are exposed by the patterning of the third liner 106C. The third liner 106C, when etched, has vertical portions left on the sidewalls of the second liner 106B. The remaining vertical portions of the third liner 106C are along the edges of the upper integrated circuit die 50B. As a result, the gap-fill dielectric 106 still has a nitride-oxide-nitride-oxide structure along the edges of the upper integrated circuit die 50B.

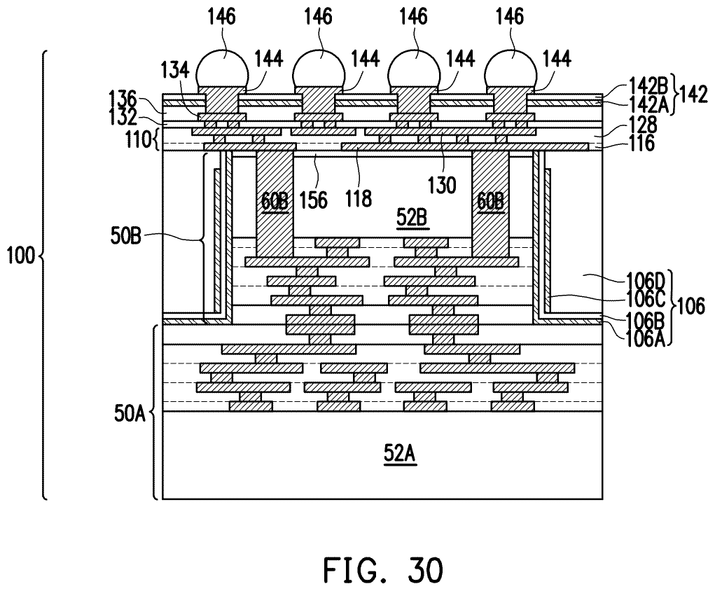

In this embodiment, the third liner 106C is patterned such that the top surfaces of the third liner 106C are inclined top surfaces. Specifically, each top surface of the third liner 106C forms an acute angle with an inner sidewall of the third liner 106C and forms an obtuse angle with an outer sidewall of the third liner 106C. In another embodiment (subsequently described for FIG. 30), the top surfaces of the third liner 106C are flat top surfaces.

As subsequently described in greater detail, the semiconductor substrate 52B will be recessed so that the conductive vias 60B protrude from the inactive surface of the semiconductor substrate 52B. The third liner 106C is patterned such that the top surfaces of the third liner 106C are beneath the top surfaces of the conductive vias 60B. As a result, when the semiconductor substrate 52B is subsequently recessed to expose the conductive vias 60B, the third liner 106C is not etched.

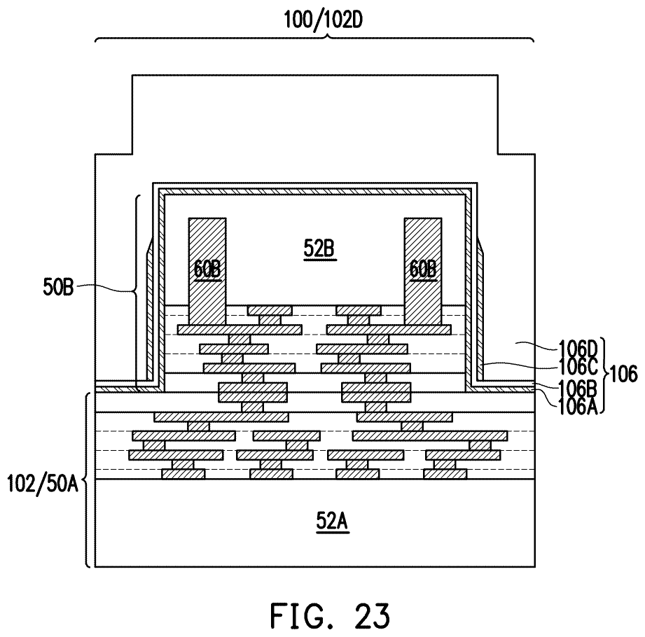

In FIG. 23, the main layer of the gap-fill dielectric 106, e.g., the main filler 106D, is formed on the liner layer(s) of the gap-fill dielectric 106, e.g., the third liner 106C and the second liner 106B. The main filler 106D may be formed in a similar manner as previously described for FIG. 4.

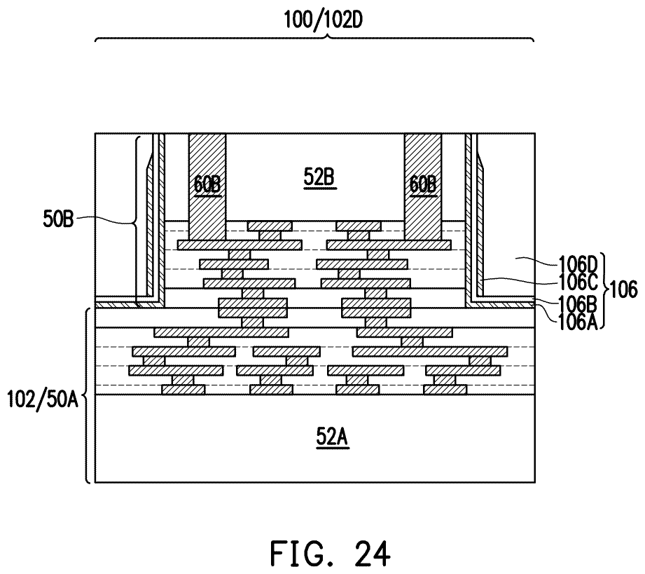

In FIG. 24, a removal process is performed to level surfaces of the gap-fill dielectric 106 with the back-side of the upper integrated circuit die 50B (e.g., the inactive surface of the semiconductor substrate 52B). The removal process may be performed in a similar manner as previously described for FIG. 6. The removal process may include removing a portion of the gap-fill dielectric 106 above the upper integrated circuit die 50B by etching, in a similar manner as previously described for FIG. 5. Additionally, the semiconductor substrate 52B may be thinned to expose the conductive vias 60B, in a similar manner as previously described for FIG. 6. After the removal process, the third liner 106C remains buried and covered by the main filler 106D. The main filler 106D extends along the outer sidewalls and the top surfaces of the third liner 106C.

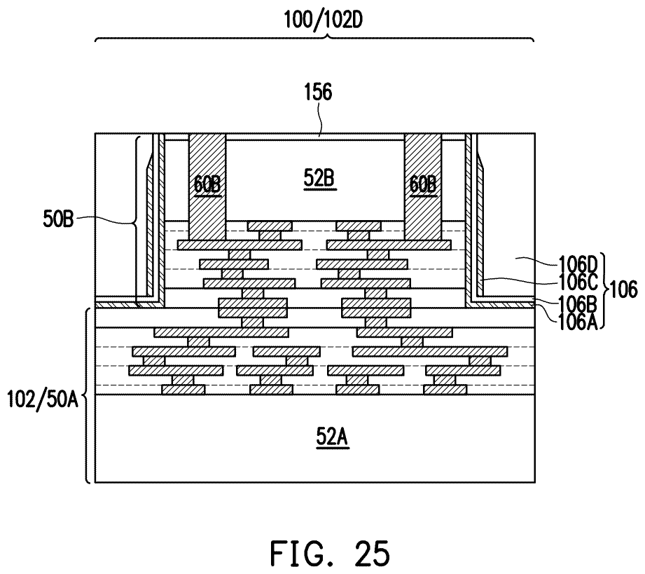

In FIG. 25, an isolation layer 156 is optionally formed around the conductive vias 60B of the upper integrated circuit die 50B. The isolation layer 156 can help electrically isolate the conductive vias 60B from one another, thus avoiding shorting, and can also be utilized in a subsequent bonding process. Additionally, the isolation layer 156 helps protect the inactive surface of the semiconductor substrate 52B. As an example to form the isolation layer 156, the semiconductor substrate 52B is recessed so the conductive vias 60B protrude from the inactive surface of the semiconductor substrate 52B. The recessing exposes portions of the sidewalls of the conductive vias 60B. The recessing may be by an etching process, such as a dry etch, a wet etch, or combinations thereof. A dielectric material can then be formed in the recess. The dielectric material can be an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as chemical vapor deposition (CVD), atomic layer deposition (ALD), or the like. Other suitable dielectric materials, such as a low temperature polyimide material, PBO, an encapsulant, combinations of these, or the like may also be utilized. A planarization process, such as a CMP, grinding, or etch-back, can be performed to remove excess portions of the dielectric material over the conductive vias 60B. The remaining portions of the dielectric material in the recess form the isolation layer 156. The isolation layer 156 laterally surrounds portions of the sidewalls of the respective conductive vias 60B.

As previously noted, the third liner 106C is recessed so that it is buried and covered by the main filler 106D. The top surfaces of the third liner 106C are beneath the inactive surface of the semiconductor substrate 52B. The top surfaces of the first liner 106A, the second liner 106B, and the main filler 106D are above the inactive surface of the semiconductor substrate 52B, and are substantially coplanar (within process variations) with the top surfaces of the conductive vias 60B and the isolation layer 156. The third liner 106C is thus not etched during the recessing of the semiconductor substrate 52B, thereby reducing pin hole defects in the die structure 100. Reducing pin hole defects can improve the yield and reliability of the die structure 100.

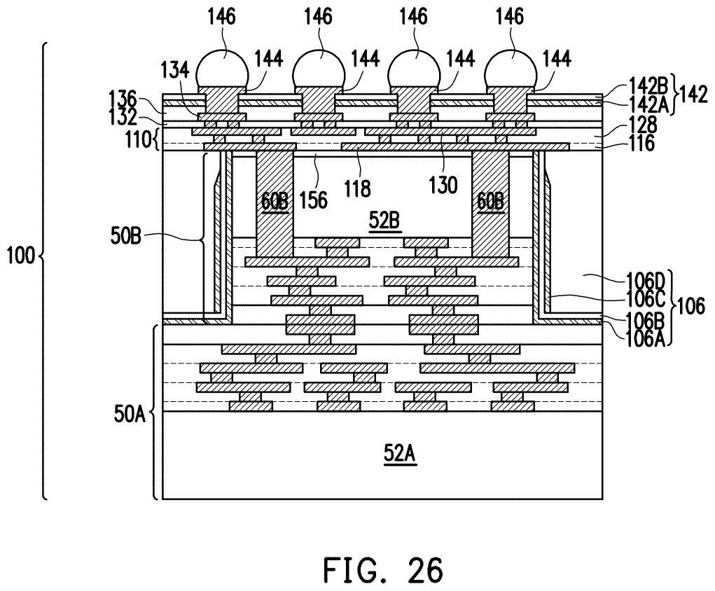

In FIG. 26, appropriate processing as previously described for FIGS. 8-11 is performed to complete the die structure 100. Because the conductive vias 60B protrude from the inactive surface of the semiconductor substrate 52B in this embodiment, the conductive vias 114 and the dielectric layer 112 may be omitted. Accordingly, the conductive lines 118 extend through the dielectric layer 116 to contact the conductive vias 60B. The width of a conductive via 60B is less than the width of a conductive line 118 contacting the conductive via 60B.

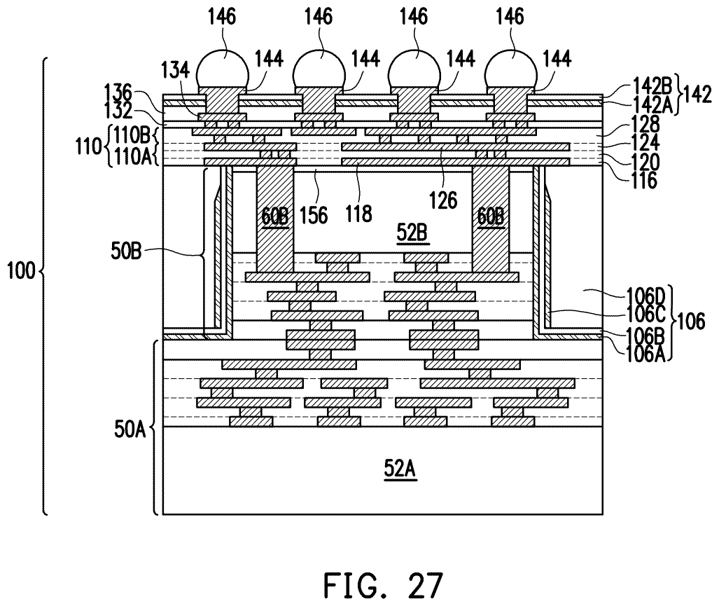

FIG. 27 is a cross-sectional view of a die structure 100, in accordance with some embodiments. This embodiment is similar to the embodiment of FIG. 26, except the lower portion 110A of the back-side interconnect structure 110 further includes dielectric layers 120, 124 and an additional layer of conductive lines and vias. Specifically, the lower portion 110A of the back-side interconnect structure 110 further includes conductive vias 122 and conductive lines 126 in the dielectric layers 120, 124.

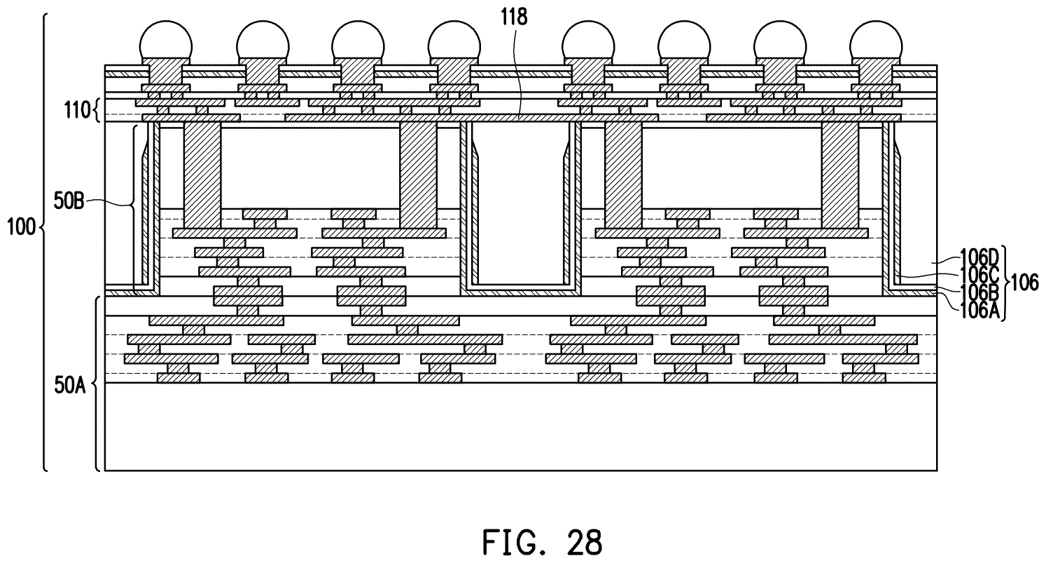

FIG. 28 is a cross-sectional view of a die structure 100, in accordance with some embodiments. This embodiment is similar to the embodiment of FIG. 26, except multiple upper integrated circuit dies 50B are bonded to the lower integrated circuit die 50A. The gap-fill dielectric 106 fills the gap(s) between the upper integrated circuit dies 50B. The upper integrated circuit dies 50B may be interconnected at least in part by some of the conductive lines 118. Additionally, some of the conductive vias 154 may be utilized for interconnecting the upper integrated circuit dies 50B. For example, a conductive via 154 may be used to connect a back-side of an upper integrated circuit die 50B to a front-side of another upper integrated circuit die 50B, through a die connector 64A of the lower integrated circuit die 50A.

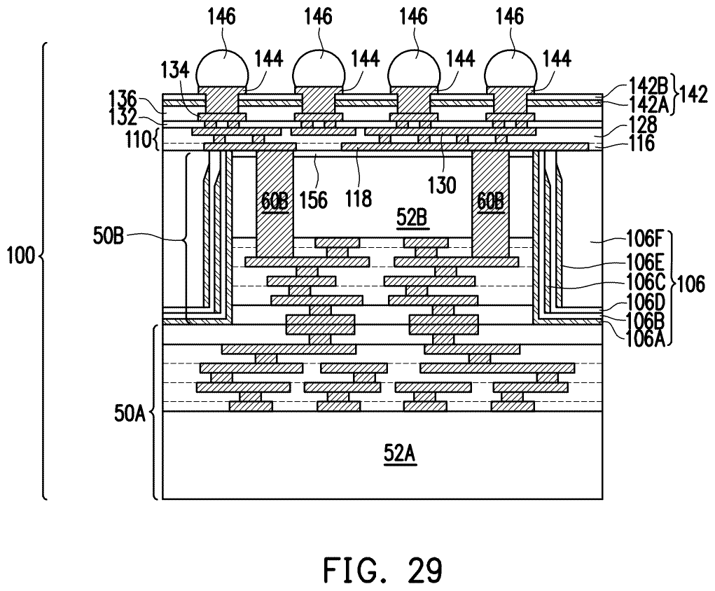

FIG. 29 is a cross-sectional view of a die structure 100, in accordance with some embodiments. This embodiment is similar to the embodiment of FIG. 26, except the gap-fill dielectric 106 includes a first liner 106A, a second liner 106B, a third liner 106C, a fourth liner 106D, a fifth liner 106E, and a main filler 106F. The fifth liner 106E may be formed in a similar manner as the third liner 106C, e.g., recessed so that it is buried and covered by the main filler 106DF.

FIG. 30 is a cross-sectional view of a die structure 100, in accordance with some embodiments. This embodiment is similar to the embodiment of FIG. 26, except the top surfaces of the third liner 106C are flat top surfaces. Specifically, each top surface of the third liner 106C forms a right angle with an inner sidewall of the third liner 106C and forms a right angle with an outer sidewall of the third liner 106C.

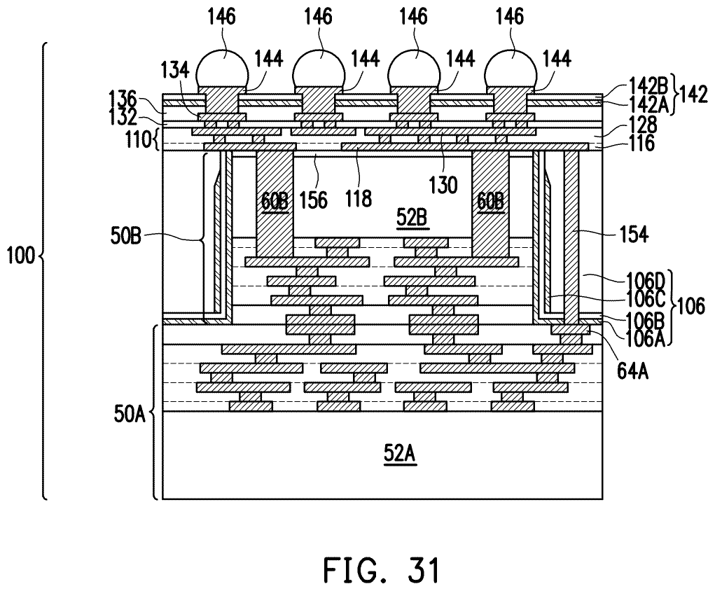

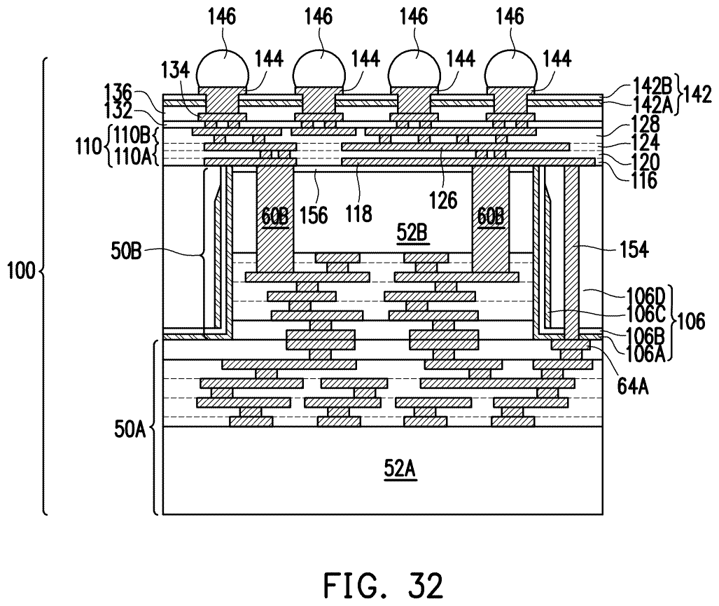

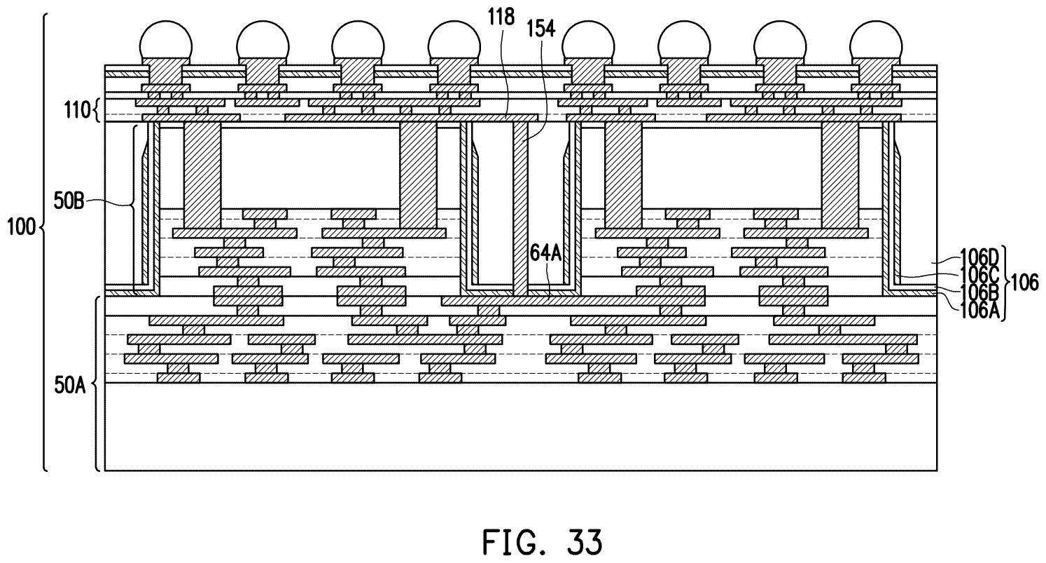

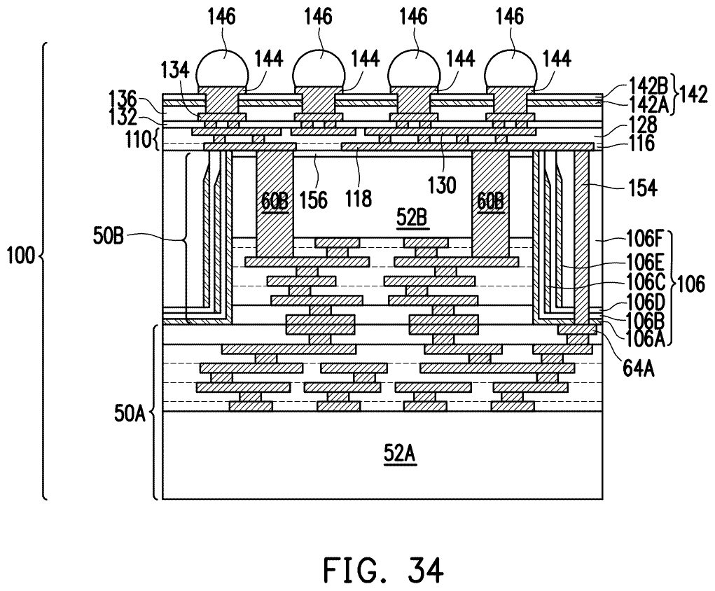

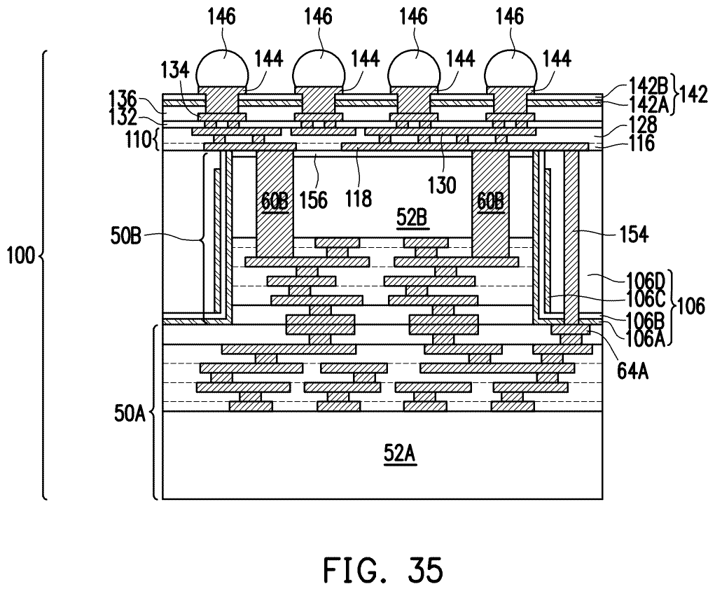

FIGS. 31-35 are cross-sectional views of die structures 100, in accordance with some embodiments. These embodiments are similar to the embodiments of FIGS. 26-30, except the die structure 100 includes through-dielectric vias (TDVs) that extend through dielectric materials to help connect the lower integrated circuit die 50A to the conductive features of the back-side interconnect structure 110. The TDVs may be formed during the formation of the back-side interconnect structure 110, in a similar manner as previously described for FIGS. 21-26.

In an embodiment, a device includes: a lower integrated circuit die; a first upper integrated circuit die face-to-face bonded to the lower integrated circuit die, the first upper integrated circuit die including a first semiconductor substrate and a first through-substrate via; a gap-fill dielectric around the first upper integrated circuit die, a top surface of the gap-fill dielectric being substantially coplanar with a top surface of the first semiconductor substrate and with a top surface of the first through-substrate via; and an interconnect structure including a first dielectric layer and first conductive vias, the first dielectric layer disposed on the top surface of the gap-fill dielectric and the top surface of the first semiconductor substrate, the first conductive vias extending through the first dielectric layer to contact the top surface of the first through-substrate via. In some embodiments of the device, the interconnect structure further includes a second dielectric layer and a first conductive line, the second dielectric layer disposed on the first dielectric layer, the first conductive line extending through the second dielectric layer to contact each of the first conductive vias. In some embodiments of the device, the interconnect structure further includes a third dielectric layer and conductive features, the third dielectric layer disposed on the second dielectric layer, the conductive features including second conductive lines and second conductive vias in the third dielectric layer. In some embodiments of the device, a width of each of the first conductive vias is less than half a width of the first through-substrate via. In some embodiments of the device, each of the first conductive vias is spaced apart from the first semiconductor substrate. In some embodiments of the device, the gap-fill dielectric includes a nitride-oxide-nitride-oxide structure. In some embodiments of the device, the gap-fill dielectric includes an epoxy material. In some embodiments, the device further includes: a second upper integrated circuit die bonded to the lower integrated circuit die, the gap-fill dielectric disposed around the second upper integrated circuit die, the second upper integrated circuit die including a second semiconductor substrate and a second through-substrate via, the top surface of the gap-fill dielectric being substantially coplanar with a top surface of the second semiconductor substrate and with a top surface of the second through-substrate via; where the interconnect structure further includes second conductive vias extending through the first dielectric layer to contact the top surface of the second through-substrate via. In some embodiments, the device further includes: a through-dielectric via extending through the first dielectric layer of the interconnect structure and through the gap-fill dielectric, where the interconnect structure further includes a conductive line contacting the through-dielectric via.

In an embodiment, a device includes: a lower integrated circuit die; an upper integrated circuit die face-to-face bonded to the lower integrated circuit die, the upper integrated circuit die including a semiconductor substrate and a through-substrate via, the through-substrate via protruding from a surface of the semiconductor substrate; a dielectric feature around the upper integrated circuit die, the dielectric feature including: a first nitride liner on a sidewall of the upper integrated circuit die; an oxide liner on the first nitride liner; a second nitride liner on the oxide liner, a top surface of the second nitride liner being disposed below the surface of the semiconductor substrate; and an oxide filler on the second nitride liner, where a top surface of the oxide filler, a top surface of the oxide liner, and a top surface of the first nitride liner are disposed above the surface of the semiconductor substrate. In some embodiments, the device further includes: an isolation layer around the through-substrate via, a top surface of the isolation layer substantially coplanar with the top surface of the oxide filler, the top surface of the oxide liner, and the top surface of the first nitride liner; a dielectric layer on the isolation layer and the dielectric feature; and a conductive line extending through the dielectric layer to contact the through-substrate via, a width of the through-substrate via being less than a width of the conductive line. In some embodiments of the device, the lower integrated circuit die includes a first die connector and a first dielectric layer, the upper integrated circuit die further includes a second die connector and a second dielectric layer, the first die connector is directly bonded to the second die connector, and the first dielectric layer is directly bonded to the second dielectric layer. In some embodiments of the device, the top surface of the second nitride liner is an inclined top surface. In some embodiments of the device, the top surface of the second nitride liner is a flat top surface.

In an embodiment, a method includes: bonding a first front-side of a first integrated circuit die to a second front-side of a second integrated circuit die, the first integrated circuit die including a semiconductor substrate and a through-substrate via; forming a gap-fill dielectric on the first integrated circuit die and on the second integrated circuit die; planarizing the gap-fill dielectric until the gap-fill dielectric, the semiconductor substrate, and the through-substrate via have top surfaces that are substantially coplanar; depositing a first dielectric layer on the top surfaces of the gap-fill dielectric, the semiconductor substrate, and the through-substrate via; and forming conductive vias in the first dielectric layer, the conductive vias extending through the first dielectric layer to contact the top surface of the through-substrate via. In some embodiments of the method, forming the gap-fill dielectric includes forming a oxide-nitride-oxide structure on the first integrated circuit die and on the second integrated circuit die. In some embodiments of the method, forming the gap-fill dielectric includes forming an epoxy material on the first integrated circuit die and on the second integrated circuit die. In some embodiments, the method further includes: forming a through-dielectric via extending through the first dielectric layer and through the gap-fill dielectric; depositing a second dielectric layer on the through-dielectric via, the conductive vias, and the first dielectric layer; and forming conductive lines in the second dielectric layer, the conductive lines extending through the second dielectric layer to contact the through-dielectric via and the conductive vias. In some embodiments, the method further includes: depositing a second dielectric layer on the conductive vias and the first dielectric layer; forming conductive lines in the second dielectric layer, the conductive lines extending through the second dielectric layer to contact the conductive vias; depositing a third dielectric layer on the conductive lines and the second dielectric layer; and forming conductive features in the third dielectric layer, where the conductive vias and the conductive lines are each formed in a single damascene process, and where the conductive features are formed in a dual damascene process. In some embodiments of the method, bonding the first front-side of the first integrated circuit die to the second front-side of the second integrated circuit die includes bonding the first integrated circuit die to a wafer including the second integrated circuit die, the gap-fill dielectric is formed on the wafer, and the method further includes: singulating the wafer, where the second integrated circuit die, the gap-fill dielectric, and the first dielectric layer are laterally coterminous after singulating the wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding an upper integrated circuit die to a lower integrated circuit die, the upper integrated circuit die comprising a semiconductor substrate and a through-substrate via;
forming a gap-fill dielectric around the upper integrated circuit die;
forming a back-side interconnect structure on the gap-fill dielectric and on the semiconductor substrate of the upper integrated circuit die, wherein forming the back-side interconnect structure comprises:
forming a lower portion of the back-side interconnect structure with a single damascene process, the lower portion of the back-side interconnect structure comprising a dielectric layer and a plurality of conductive vias, each of the conductive vias extending through the dielectric layer to contact the through-substrate via; and
forming an upper portion of the back-side interconnect structure with a dual damascene process.

2. The method of claim 1, further comprising:
planarizing the gap-fill dielectric until a top surface of the gap-fill dielectric is coplanar with an inactive surface of the semiconductor substrate,
wherein forming the lower portion of the back-side interconnect structure comprises:
depositing the dielectric layer in physical contact with the top surface of the gap-fill dielectric and with the inactive surface of the semiconductor substrate; and
forming the conductive vias in the dielectric layer.

3. The method of claim 1, further comprising:
singulating the lower integrated circuit die, the gap-fill dielectric, and the back-side interconnect structure, wherein sidewalls of the lower integrated circuit die, the gap-fill dielectric, and the back-side interconnect structure are laterally coterminous.

4. The method of claim 1, wherein forming the gap-fill dielectric comprises:
depositing a first nitride liner on sidewalls of the upper integrated circuit die;
depositing an oxide liner on the first nitride liner;
depositing a second nitride liner on the oxide liner; and
depositing an oxide filler on the second nitride liner.

5. The method of claim 1, wherein forming the gap-fill dielectric comprises:
applying an epoxy material around the upper integrated circuit die using compression molding or transfer molding.

6. The method of claim 1, wherein each of the conductive vias is smaller than the through-substrate via.

7. The method of claim 1, further comprising:
forming a through-dielectric via extending through the dielectric layer and through the gap-fill dielectric, the through-dielectric via being coupled to the lower integrated circuit die.

8. A method comprising:
bonding a first integrated circuit die to a second integrated circuit die with dielectric-to-dielectric bonds and with metal-to-metal bonds, the first integrated circuit die comprising a semiconductor substrate and a through-substrate via, the second integrated circuit die comprising a die connector;
forming a gap-fill dielectric around the first integrated circuit die;
depositing a first dielectric layer on the gap-fill dielectric and on the semiconductor substrate of the first integrated circuit die;
forming a plurality of conductive vias in the first dielectric layer, the conductive vias extending through the first dielectric layer to contact the through-substrate via;
forming a through-dielectric via extending through the first dielectric layer and the gap-fill dielectric to contact the die connector of the second integrated circuit die;
depositing a second dielectric layer on the through-dielectric via, the conductive vias, and the first dielectric layer; and
forming a conductive line in the second dielectric layer, the conductive line extending through the second dielectric layer to contact the conductive vias and the through-dielectric via.

9. The method of claim 8, wherein a width of each of the conductive vias is less than half a width of the through-substrate via.

10. The method of claim 8, wherein each of the conductive vias is spaced apart from the semiconductor substrate of the first integrated circuit die.

11. The method of claim 8, wherein the first integrated circuit die is face-to-face bonded to the second integrated circuit die such that a first front-side of the first integrated circuit die faces towards a second front-side of the second integrated circuit die.

12. The method of claim 8, wherein forming the gap-fill dielectric comprises forming a nitride-oxide-nitride-oxide structure around the first integrated circuit die.

13. The method of claim 8, wherein forming the gap-fill dielectric comprises molding an epoxy material around the first integrated circuit die.

14. The method of claim 8, wherein the second integrated circuit die is wider than the first integrated circuit die.

15. The method of claim 8, wherein the first integrated circuit die comprises a memory die and the second integrated circuit die comprises a logic die.

16. A method comprising:
bonding a first upper integrated circuit die and a second upper integrated circuit die to a lower integrated circuit die, the first upper integrated circuit die and the second upper integrated circuit die each comprising a semiconductor substrate and a through-substrate via;
forming a gap-fill dielectric in a gap between the first upper integrated circuit die and the second upper integrated circuit die;
forming a back-side interconnect structure comprising:
a first dielectric layer on the gap-fill dielectric, on the semiconductor substrate of the first upper integrated circuit die, and on the semiconductor substrate of the second upper integrated circuit die;
a plurality of first conductive vias extending through the first dielectric layer to contact the through-substrate via of the first upper integrated circuit die;
a plurality of second conductive vias extending through the first dielectric layer to contact the through-substrate via of the second upper integrated circuit die;
a second dielectric layer on the first conductive vias, the second conductive vias, and the first dielectric layer; and
a first conductive line extending through the second dielectric layer to contact each of the first conductive vias and each of the second conductive vias.

17. The method of claim 16, wherein the gap-fill dielectric comprises a nitride-oxide-nitride-oxide structure.

18. The method of claim 16, wherein the gap-fill dielectric comprises an epoxy material.

19. The method of claim 16, wherein the back-side interconnect structure further comprises:
a third dielectric layer on the first conductive line and the second dielectric layer; and
a conductive feature in the third dielectric layer, the conductive feature comprising a second conductive line and a third conductive via that connects the second conductive line to the first conductive line.

20. The method of claim 19, wherein the first conductive vias and the second conductive vias are formed in a single damascene process, the first conductive line is formed in a single damascene process, and the conductive feature is formed in a dual damascene process.
